(19) United States
(12) Patent Application Publication
(10) Pub. No.: US 2026/0076054 A1
(43) Pub. Date: Mar. 12, 2026

(54) ELECTRONIC DEVICE

(71) Applicant: Samsung Display Co., Ltd., Yongin-si (KR)

(72) Inventors: HEE-KWANG SONG, Yongin-si (KR); SHINMOON KANG, Yongin-si (KR)

(73) Assignee: Samsung Display Co., Ltd., Yongin-si (KR)

(21) Appl. No.: 19/247,462

(22) Filed: Jun. 24, 2025

(30) Foreign Application Priority Data
Sep. 12, 2024 (KR) 10-2024-0125066

(51) Int. Cl. H10K 59/38; H10H 29/37; H10H 29/80; H10H 29/85; H10H 29/851; H10K 59/122; H10K 59/32; H10K 102/00

(52) U.S. Cl. CPC H10K 59/38; H10H 29/37; H10H 29/8513; H10H 29/8517; H10H 29/962; H10K 59/122; H10K 59/32; H10K 2102/331

(57) ABSTRACT

An electronic device includes a pixel defining film defining a plurality of emission areas and a non-emission area, a plurality of light emitting elements which are disposed in the emission areas, respectively, and emit source light, and an optical layer disposed on the light emitting elements. The light emitting elements each include a first electrode, a first emission layer generating first light of a blue color, a second emission layer generating second light of a green color, a third emission layer generating third light of the blue color, a fourth emission layer generating fourth light of the blue color, a charge generation layer, and a second electrode. The pixel defining film includes a pigment having a black color, and a distance between the first and second electrodes is less than a resonance distance of green light.

### CROSS-REFERENCE TO RELATED APPLICATION(S)

This application claims priority to and benefits of Korean Patent Application No. 10-2024-0125066 under 35 U.S.C. § 119, filed on Sep. 12, 2024, in the Korean Intellectual Property Office, the entire contents of which are incorporated herein by reference.

### BACKGROUND

### 1. Technical Field

The disclosure herein relates to an electronic device capable of compensating for image sticking.

### 2. Description of the Related Art

Among display devices, emissive display devices display images using light emitting diodes which generate light by recombination of electrons and holes. These emissive display devices have merits of having a speedy response time and also being driven at low power consumption.

The emissive display devices include display panels on which pixels coupled to data lines and scan lines are disposed. Generally, the pixels include a light emitting diode and a pixel circuit part for controlling an amount of current flowing to the light emitting diode. The pixel circuit part controls the amount of the current flowing via the light emitting diode in response to a data signal. Here, light having a luminance corresponding to the amount of the current flowing through the light emitting diode is generated.

### SUMMARY

The disclosure provides an electronic device capable of effectively compensating for image sticking by reducing a period of time in which a relative value of an output luminance value to an initial luminance value is greater than about 1.

According to an embodiment of the disclosure, an electronic device may include a pixel defining film defining a plurality of emission areas and a non-emission area adjacent to the plurality of emission areas, a plurality of light emitting elements which are disposed in the plurality of emission areas, respectively, and each of which emits source light, and an optical layer disposed on the plurality of light emitting elements. Each of the plurality of light emitting elements may include a first electrode disposed in the plurality of emission areas, a first emission layer disposed on the first electrode and generating first light of a blue color, a second emission layer disposed on the first emission layer and generating second light of a green color, a third emission layer disposed between the first emission layer and the second emission layer and generating third light of the blue color, a fourth emission layer disposed between the first emission layer and the second emission layer and generating fourth light of the blue color, a charge generation layer disposed between the first emission layer and the second emission layer, and a second electrode disposed on the second emission layer. The pixel defining film may include a pigment having a black color, and a distance between the first electrode and the second electrode may be less than a resonance distance of green light.

In an embodiment, a maximum value of differences between a maximum overshoot value of the second light and a maximum overshoot value of each of the first light, the third light, and the fourth light may be about 0.01.

In an embodiment, the maximum overshoot value may be measured at 64-gradation or 128-gradation.

In an embodiment, wavelengths of at least two of the first light, the third light, and the fourth light may be different from each other.

In an embodiment, the wavelengths may be in a range of about 440 nm to about 610 nm.

In an embodiment, the optical layer may include a color filter layer including a color filter.

In an embodiment, the optical layer may further include a light control layer including a quantum dot.

In an embodiment, each of the first emission layer, the third emission layer, and the fourth emission layer may include a plurality of stacked layers.

In an embodiment of the disclosure, an electronic device may include a display module configured to display an image and a processor configured to provide image data to the display module. The display module comprises a pixel defining film defining a plurality of emission areas and a non-emission area adjacent to the plurality of emission areas, a plurality of light emitting elements which are disposed in the plurality of emission areas, respectively, and each of which emits source light, and an optical layer disposed on the plurality of light emitting elements. Each of the plurality of light emitting elements may include a first electrode disposed in the plurality of emission areas, a second electrode disposed on the first electrode, a first emission layer disposed between the first electrode and the second electrode and generating first light, a second emission layer disposed between the first electrode and the second electrode and generating second light, the first light and the second light having different colors, and a charge generation layer disposed between the first emission layer and the second emission layer. Each of the first light and the second light may have an overshoot value having a luminance higher than an initial luminance for a period of time, and a difference between a maximum overshoot value of the first light and a maximum overshoot value of the second light may be about 0.01.

In an embodiment, a wavelength of the first light may be shorter than a wavelength of the second light.

In an embodiment, each of the plurality of light emitting elements may further include a third emission layer and a fourth emission layer, and the third emission layer and the fourth emission layer may generate light of a same color as the first light.

In an embodiment, the second emission layer may be disposed on the first emission layer, and the third emission layer and the fourth emission layer may be disposed between the first emission layer and the second emission layer.

In an embodiment, each of the first emission layer, the third emission layer, and the fourth emission layer may include a plurality of stacked layers.

In an embodiment, wavelengths of lights from at least two of the first emission layer, the third emission layer, and the fourth emission layer may be different from each other.

In an embodiment, the wavelengths may be in a range of about 440 nm to about 610 nm.

In an embodiment, the pixel defining film may include at least one of a black pigment and a black dye.

In an embodiment, the optical layer may include a color filter layer including a color filter.

In an embodiment, the optical layer may further include a light control layer including a quantum dot.

In an embodiment, a distance between the first electrode and the second electrode may be less than a resonance distance of the second light.

In an embodiment, the maximum overshoot value may be measured at 64-gradation or 128-gradation.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a perspective view of a display device according to an embodiment of the disclosure;

FIG. 2 is a schematic cross-sectional view of a display device according to an embodiment of the disclosure;

FIG. 3 is a plan view of a partial area of a display device according to an embodiment of the disclosure;

FIG. 4A is a schematic cross-sectional view of a display device according to an embodiment of the disclosure;

FIG. 4B is a schematic cross-sectional view of a display device according to an embodiment of the disclosure;

FIG. 5 is a schematic cross-sectional view of a light emitting element according to an embodiment of the disclosure;

FIG. 6 is a graph showing a time-relative output luminance curve for a display panel according to an embodiment of the disclosure;

FIG. 7A is a graph showing a time-relative output luminance curve for a display panel according to an embodiment of the disclosure;

FIG. 7B is a graph showing a time-relative output luminance curve for a display panel according to an embodiment of the disclosure;

FIG. 8A is a graph showing a time-relative output luminance curve for a display panel according to an embodiment of the disclosure; and

FIG. 8B is a graph showing a time-relative output luminance curve for a display panel according to an embodiment of the disclosure.

FIG. 9 is a block diagram illustrating an electronic device according to an embodiment.

FIG. 10 is a view schematically illustrating an electronic device according to an embodiment.

### DETAILED DESCRIPTION OF THE EMBODIMENTS

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like reference numbers or symbols refer to like elements throughout. In addition, in the drawings, the thickness, the ratio, and the dimension of elements are exaggerated for effective description of the technical contents.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms first, second, etc. may be used herein to describe various elements, these elements should not be limited by these terms. These terms are only used to distinguish one element from another element. For example, a first element could be termed a second element without departing from the teachings of the disclosure, and similarly, a second element could be termed a first element. As used herein, the singular forms are intended to include the plural forms as well, unless the context clearly indicates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The term “about” may include variations of, for example, ±20%, ±10%, or ±5%, from the specified numerical value unless otherwise expressly stated. In some contexts, the term may account for rounding, inherent measurement limitations, or standard tolerances recognized in the relevant technical field. When applied to dimensions, concentrations, or other quantifiable parameters, “about” may include minor deviations that would be understood by a person of ordinary skill in the art as insubstantial in the given context. The scope of “about” should be interpreted in view of standard experimental or clinical tolerances applicable to the field of use. A person skilled in the art would recognize that “about” allows for practical deviations that do not materially alter the intended properties of the invention. Similarly, for mechanical dimensions, “about” may include deviations that are within industry-accepted tolerances and do not materially impact the performance of the invention.

It will be further understood that the terms such as “includes” or “has”, when used herein, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described with reference to the accompanying drawings.

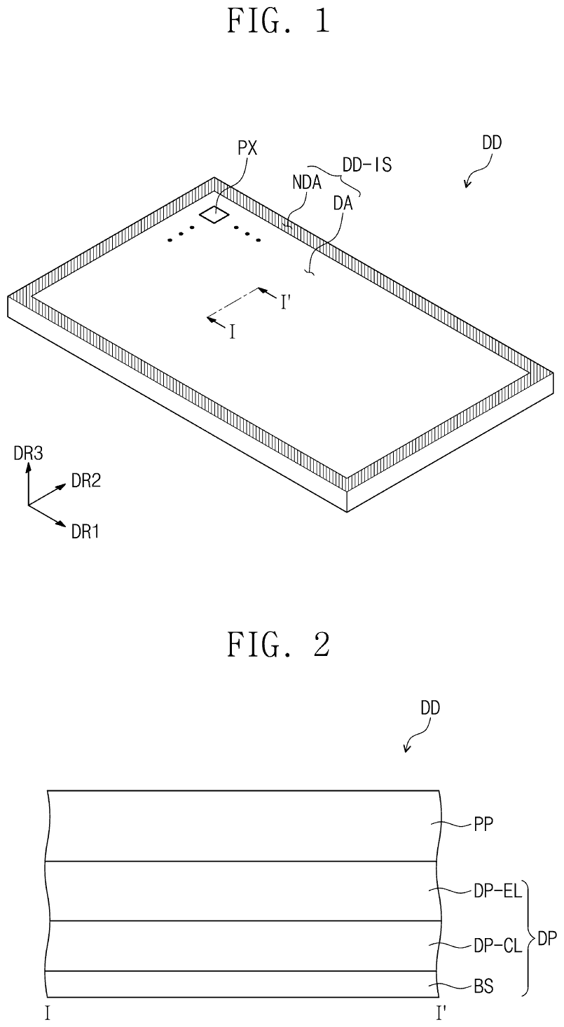

Referring to FIG. 1, a display device DD according to an embodiment may be a device that is activated in response to an electrical signal. For example, the display device DD may be a large-sized device such as a television, a monitor, or an outdoor billboard. For example, the display device DD may be a small- and medium-sized device such as a personal computer, a notebook computer, a personal digital assistant, a vehicle navigation unit, a game console, a smartphone, a tablet computer, and a camera. However, the disclosure is not limited thereto, and the display device DD may be employed as another electronic device unless departing from the disclosure.

The display device DD may display an image through a display surface DD-IS. The display surface DD-IS may be parallel to a plane defined by a first direction DR1 and a second direction DR2. The display surface DD-IS may include a display area DA and a non-display area NDA.

A pixel PX may be disposed in the display area DA, and may not be disposed in the non-display area NDA. The non-display area NDA may be defined along an edge of the display surface DD-IS. The non-display area NDA may surround the display area DA. However, the disclosure is not limited thereto. The non-display area NDA may be omitted or the non-display area NDA may be disposed at only a side of the display area DA.

FIG. 1 schematically illustrates the display device DD provided with a flat display surface DD-IS, but the disclosure is not limited thereto. In another embodiment, the display device DD may include a curved display surface or a three-dimensional display surface. The three-dimensional display surface may include multiple display areas facing different directions.

A thickness direction of the display device DD may be a direction parallel to a third direction DR3 that is a normal direction to a plane defined by the first direction DR1 and the second direction DR2. Directions indicated by the first to third directions DR1, DR2 and DR3 used herein are relative concepts and may be changed to other directions.

In the disclosure, a top surface (or front surface) and a bottom surface (or rear surface) of each of members, which constitute the display device DD, may be defined on the basis of the third direction DR3. For example, among two surfaces of one member facing each other on the basis of the third direction DR3, a surface relatively adjacent to the display surface DD-IS may be defined as the front surface (or top surface), and a surface relatively spaced apart from the display surface DD-IS may be defined as the rear surface (or bottom surface). In addition, the terms “upper” and “lower” used herein may be defined on the basis of the third direction DR3. The term “upper” may be defined as a direction that is closer to the display surface DD-IS, and the term “lower” may be defined as a direction that is away from the display surface DD-IS.

FIG. 2 is a schematic cross-sectional view of a display device according to an embodiment of the disclosure. FIG. 2 is a schematic cross-sectional view of a display device DD according to an embodiment corresponding to line I-I′ in FIG. 1.

Referring to FIG. 2, the display device DD according to an embodiment may include a display panel DP and an optical structure layer PP disposed on the display panel DP. The display panel DP may include a display element layer DP-EL. The display element layer DP-ED may include a light emitting element ED.

The optical structure layer PP may be disposed on the display panel DP and control reflected light from the display panel DP by external light. The optical structure layer PP may include, for example, a color filter layer and may include an anti-reflective layer. The optical structure layer PP will be described below in detail.

In the display device DD according to an embodiment, the display panel DP may be an emissive display panel. For example, the display panel DP may be a light-emitting diode (LED) display panel, an organic electroluminescence display panel, or a quantum dot light-emitting display panel. However, the disclosure is not limited thereto. The display panel DP may provide first light.

A light-emitting diode (LED) display panel may include a light emitting diode, an emission layer of an organic electroluminescence display panel may include an organic electroluminescence light-emitting material, and an emission layer of a quantum dot light-emitting display panel may include a quantum dot, a quantum rod, or the like. Hereinafter, the display panel DP included in the display device DD according to an embodiment herein is described as an organic electroluminescence display panel. However, the disclosure is not limited thereto.

The display panel DP may include a base substrate BS, a circuit layer DP-CL disposed on the base substrate BS, and the display element layer DP-EL disposed on the circuit layer DP-CL.

The base substrate BS may be a member that provides a base surface on which the display element layer DP-EL is disposed. The base substrate BS may be a glass substrate, a metal substrate, a plastic substrate, or the like. However, the disclosure is not limited thereto, and the base substrate BS may be an inorganic layer, an organic layer, or a composite material layer. The base substrate BS may be a flexible substrate which may be readily bendable or foldable.

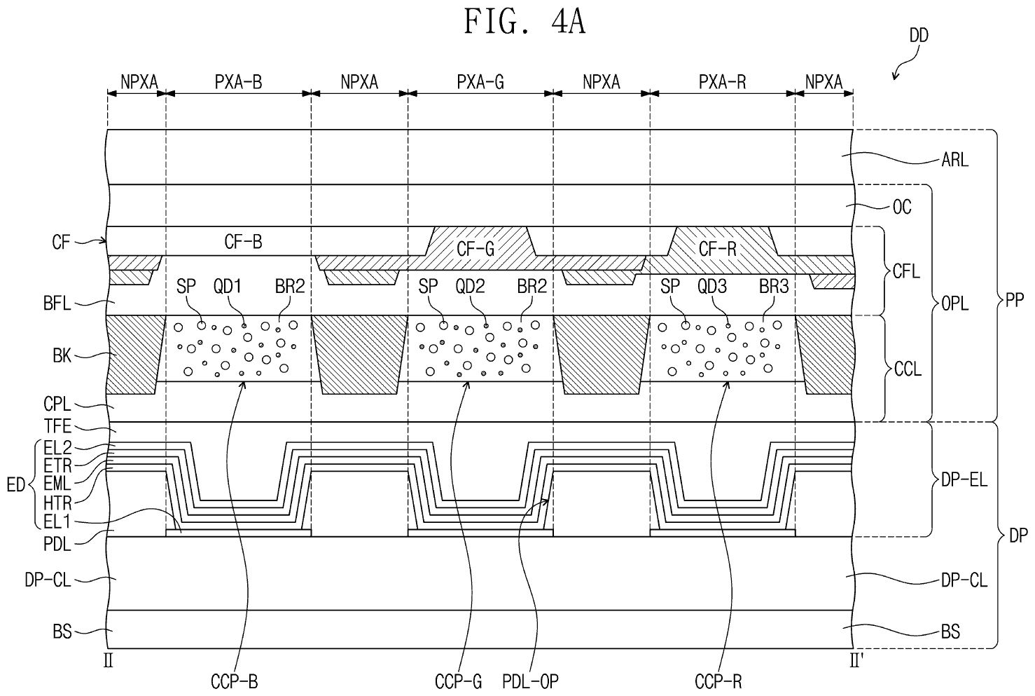

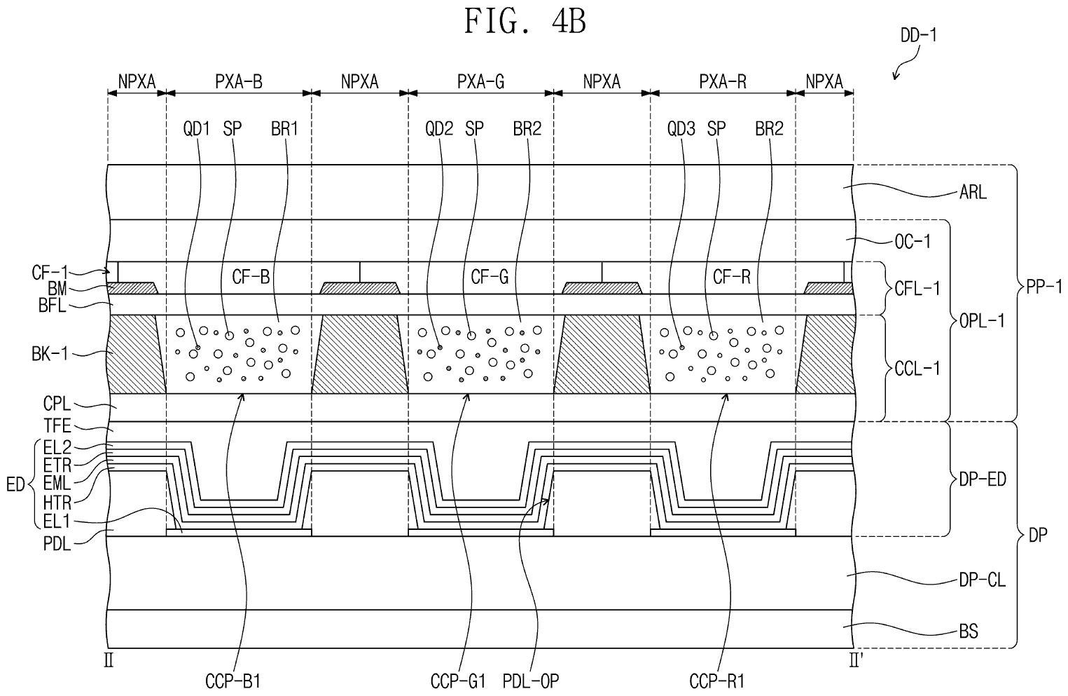

In an embodiment, the circuit layer DP-CL may be disposed on the base substrate BS, and the circuit layer DP-CL may include multiple transistors (not illustrated). The transistors (not illustrated) may each include a control electrode, an input electrode, and an output electrode. For example, the circuit layer DP-CL may include a switching transistor and a driving transistor each for driving a light emitting element ED (see FIG. 4A) of the display element layer DP-EL.

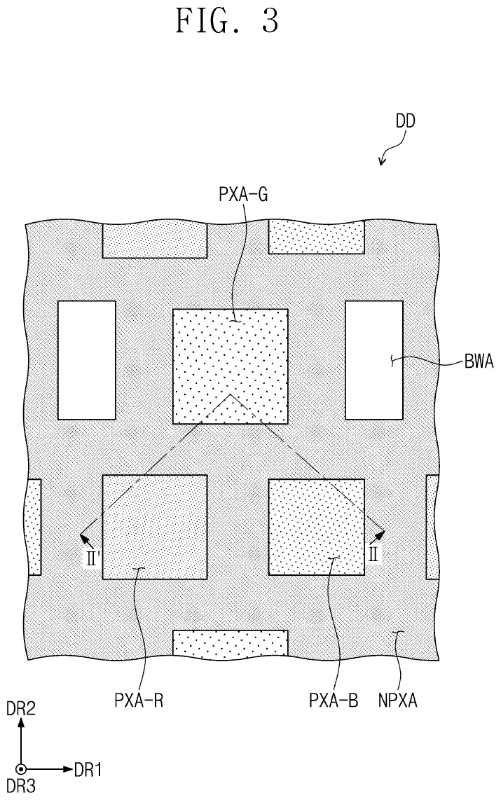

FIG. 3 is a plan view of a partial area of a display device according to an embodiment of the disclosure.

Referring to FIG. 3, a display device DD according to an embodiment may include three emission areas PXA-B, PXA-G and PXA-R and a bank well area BWA adjacent to the three emission areas PXA-B, PXA-G and PXA-R. In an embodiment of the disclosure, three types of emission areas PXA-B, PXA-G and PXA-R illustrated in FIG. 3 may be repeatedly arranged in an entire area of the display area DA (see FIG. 1).

A peripheral area NPXA may be disposed around each of first to third emission areas PXA-B, PXA-G and PXA-R. The peripheral area NPXA may set a boundary between the first to third emission areas PXA-B, PXA-G and PXA-R. The peripheral area NPXA may surround the first to third emission areas PXA-B, PXA-G and PXA-R. A structure, for example, a pixel defining film PDL (see FIG. 4A), which prevents color mixture between the first to third emission areas PXA-B, PXA-G and PXA-R, may be disposed in the peripheral area NPXA.

FIG. 3 illustrates that the first to third emission areas PXA-B, PXA-G and PXA-R have a same planar shape and have different surface areas, but the disclosure is not limited thereto. In another embodiment, at least two of the first to third emission areas PXA-B, PXA-G and PXA-R may have a same surface area. The respective surface areas of the first to third emission areas PXA-B, PXA-G and PXA-R may be set according to emissive colors. A surface area of an emission area which emits light of a green color that is one of primary colors may be the largest, and a surface area of an emission area which emits light of a blue color that is one of the primary colors may be the smallest. However, the disclosure is not limited to the embodiment illustrated in FIG. 3, and the surface areas of the first to third emission areas PXA-B, PXA-G and PXA-R may be variously changed.

FIG. 3 illustrates that the first to third emission areas PXA-B, PXA-G and PXA-R each has a rectangular shape in a plan view, but the disclosure is not limited thereto. In a plan view, the first to third emission areas PXA-B, PXA-G and PXA-R may have another polygonal shape (including substantially polygonal shape) such as rhombic shapes or pentagonal shapes. In an embodiment, the first to third emission areas PXA-B, PXA-G and PXA-R may have a rectangular shape (substantially rectangular shape) with rounded corner areas in a plan view.

FIG. 3 illustrates an embodiment that a second emission area PXA-G is disposed in a first row, and a first emission area PXA-B and a third emission area PXA-R are disposed in a second row. However, the disclosure is not limited thereto, and an arrangement of the first to third emission areas PXA-B, PXA-G and PXA-R may be variously changed. For example, the first to third emission areas PXA-B, PXA-G and PXA-R may be disposed in a same row.

The bank well area BWA may be defined in the display area DA (see FIG. 1). The bank well area BWA may be an area in which a bank well is defined to prevent defects due to ink application errors in a process of patterning multiple light control portions CCP-B, CCP-G and CCP-R (see FIG. 4A) included in a light control layer CCL (see FIG. 4A). For example, the bank well area BWA may be an area in which a bank well formed by removing a portion of partition wall portions BK (see FIG. 4A) is defined.

FIG. 3 illustrates an embodiment that two bank well areas BWA are defined adjacent to the second emission area PXA-G. However, the disclosure is not limited thereto, and the shape and arrangement of the bank well area BWA may be variously changed.

FIGS. 4A and 4B are schematic cross-sectional views of a display device according to an embodiment of the disclosure. FIGS. 4A and 4B each schematically illustrate a cross-section corresponding to cutting line II-II′ illustrated in FIG. 3.

In display devices DD and DD-1 illustrated in FIGS. 3, 4A, and 4B, three emission areas PXA-B, PXA-G and PXA-R which emit blue light, green light, and red light are illustrated according to an embodiment. For example, the display devices DD and DD-1 according to an embodiment may each include a blue emission area PXA-B, a green emission area PXA-G, and a red emission area PXA-R which are distinguished from each other.

Referring to FIGS. 4A and 4B, the display devices DD and DD-1 according to an embodiment may include display panels DP including light emitting elements ED, and optical structure layers PP and PP-1 disposed on the display panels DP, respectively.

The display panel DP may include a base substrate BS, and a circuit layer DP-CL and a display element layer DP-EL which are provided on the base substrate BS.

The display element layer DP-EL may include pixel defining films PDL, the light emitting element ED disposed between the pixel defining films PDL or on the pixel defining films PDL, and an encapsulation layer TFE disposed on the light emitting element ED.

The emission areas PXA-B, PXA-G and PXA-R may be areas divided by the pixel defining films PDL. A peripheral area NPXA may be an area between neighboring emission areas among the emission areas PXA-B, PXA-G and PXA-R and an area corresponding to the pixel defining film PDL. In the disclosure, each of the emission areas PXA-B, PXA-G and PXA-R may correspond to a pixel. As illustrated in FIG. 4A, an organic layer such as an emission layer EML included in the light emitting element ED may be provided as a common layer so as to overlap all of the emission areas PXA-B, PXA-G and PXA-R and the peripheral area NPXA in a plan view. In another embodiment, although not illustrated, the emission layer EML of the light emitting element ED may be divided by being disposed in an emission opening portion PDL-OP defined by the pixel defining film PDL.

The pixel defining film PDL may be disposed on the circuit layer DP-CL. The pixel defining film PDL may include emission opening portions PDL-OP overlapping the emission areas PXA-B, PXA-G and PXA-R in a plan view, respectively. The pixel defining film PDL may be made of a polymer resin. For example, the pixel defining film PDL may include a polyacrylate-based resin or a polyimide-based resin. The pixel defining film PDL may further include an inorganic material in addition to a polymer resin. The pixel defining film PDL may include a light absorbing material. The pixel defining film PDL may include at least one of a black pigment and a black dye. The pixel defining film PDL including a black pigment or a black dye may be a black pixel defining film. When forming the pixel defining film PDL, a carbon black or the like may be used as a black pigment or a black dye, but the disclosure is not limited thereto.

The pixel defining film PDL including at least one of a black pigment and a black dye may prevent external light from penetrating a circuit element layer, thereby reducing a phenomenon in which out-gassing occurs in the circuit element layer or the like. Accordingly, a phenomenon in which oxidation occurs in the light emitting element may be reduced to increase lifespan of the light emitting element.

The pixel defining film PDL may include an inorganic material. For example, the pixel defining film PDL may include at least one of a silicon nitride (SiNₓ), a silicon oxide (SiOₓ), a silicon oxynitride (SiOₓN_{y}), and the like. The pixel defining film PDL may define the emission areas PXA-B, PXA-G and PXA-R. The emission areas PXA-B, PXA-G and PXA-R and the peripheral area NPXA may be divided by the pixel defining film PDL.

The light emitting element ED may be disposed on the circuit layer DP-CL. The light emitting element ED may include an organic light emitting element, an inorganic light emitting element, an organic-inorganic light emitting element, a quantum dot light emitting element, a micro-LED light emitting element, or a nano-LED light emitting element. However, the disclosure is not limited thereto, and the light emitting element ED may include various embodiments as long as, in response to an electrical signal, light is generated or an amount of light is controllable.

The light emitting element ED according to an embodiment may include a first electrode EL1, a second electrode EL2 facing the first electrode EL1, and multiple functional layers including the emission layer EML disposed between the first electrode EL1 and the second electrode EL2.

The functional layers may include a hole transport region HTR disposed between the first electrode EL1 and the emission layer EML, and an electron transport region ETR disposed between the emission layer EML and the second electrode EL2. Although not illustrated in the drawing, in an embodiment, an element capping layer may be further disposed on the second electrode EL2.

Each of the hole transport region HTR and the electron transport region ETR may include multiple sub-functional layers. For example, the hole transport region HTR may include a hole injection layer and a hole transport layer as sub-functional layers, and the electron transport region ETR may include an electron injection layer and an electron transport layer as sub-functional layers. However, the disclosure is not limited thereto. The hole transport region HTR may further include an electron blocking layer or the like as a sub-functional layer, and the electron transport region ETR may further include a hole blocking layer or the like as a sub-functional layer.

The first electrode EL1 may have a conductivity. The first electrode EL1 may be made of a metal alloy or a conductive compound. The first electrode EL1 may be an anode. The first electrode EL1 may be a pixel electrode. The first electrode EL1 may be a reflective electrode. However, the disclosure is not limited thereto, and in another embodiment, the first electrode EL1 may be a transmissive electrode, a semi-transmissive electrode, or the like. In an embodiment that the first electrode EL1 is a semi-transmissive electrode or a reflective electrode, the first electrode EL1 may include at least one of Ag, Mg, Cu, Al, Pt, Pd, Au, Ni, Nd, Ir, Cr, Li, Ca, LiF/Ca, LiF/Al, Mo, Ti, a compound thereof, and a mixture thereof (e.g., a mixture of Ag and Mg). In another embodiment, the first electrode EL1 may have a multilayer structure including a reflective film or a semi-transmissive film, each of which is made of the foregoing material, and a transparent conductive film made of an indium tin oxide (ITO), an indium zinc oxide (IZO), a zinc oxide (ZnO), an indium tin zinc oxide (ITZO), or the like. For example, the first electrode EL1 may be a metal film having a multilayer structure, for example, a structure in which metal films of ITO/Ag/ITO are stacked each other.

The hole transport region HTR may be provided on the first electrode EL1. The hole transport region HTR may include a hole injection layer (not illustrated), a hole transport layer (not illustrated), and the like. The hole transport region HTR may have a layer made of a material, a layer made of different materials, or a structure having multiple layers made of different materials.

The hole transport region HTR may be formed by a method such as a vacuum deposition method, a spin coating method, a cast method, a Langmuir-Blodgett (LB) method, an inkjet printing method, a laser printing method, or a laser induced thermal imaging (LITI) method.

The hole transport region HTR may include, for example, a carbazole derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPD), 4,4′-Cyclohexylidene bis[N,N-bis(4-methylphenyl)benzenamine] (TAPC), 4,4′-Bis[N,N′-(3-tolyl)amino]-3,3′-dimethylbiphenyl (HMTPD), 1,3-Bis(N-carbazolyl)benzene (mCP), or the like.

The hole transport region HTR may have a thickness in a range of about 5 nm to about 1,500 nm. For example, the hole transport region HTR may have a thickness in a range of about 10 nm to about 500 nm. In case that the thickness of the hole transport region HTR satisfies the foregoing range, satisfactory hole transport properties may be obtained without a substantial increase in driving voltage.

The emission layer EML may be provided on the hole transport region HTR. The emission layer EML may include a host and a dopant. In an embodiment, the emission layer EML may include an organic light emitting material as a dopant material. In another embodiment, the emission layer EML may include a quantum dot as a dopant material. In an embodiment, the emission layer EML may further include an organic host material in addition to the dopant material.

In the light emitting element ED according to an embodiment, the electron transport region ETR may be provided on the emission layer EML. The electron transport region ETR may include at least one of an electron transport layer (not illustrated) and an electron injection layer (not illustrated), but the disclosure is not limited thereto.

The electron transport region ETR may have a layer made of a material, a layer made of different materials, or a structure having multiple layers made of different materials. For example, the electron transport region ETR may have a single-layer structure of an electron injection layer or an electron transport layer, or a single-layer structure made of an electron injection material and an electron transport material. The electron transport region ETR may have a thickness in a range of, for example, about 20 nm to about 150 nm.

The electron transport region ETR may be formed by a method such as a vacuum deposition method, a spin coating method, a cast method, a Langmuir-Blodgett (LB) method, an inkjet printing method, a laser printing method, or a laser induced thermal imaging (LITI) method.

The electron transport region ETR may include, for example, an anthracene-based compound, Tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, bis[2-(diphenylphosphino)phenyl]ether oxide (DPEPO), 2-(4-(N-phenylbenzoimidazolyl-1-ylphenyl)-9,10-dinaphthylanthracene, 1,3,5-Tri(1-phenyl-1H-benzo[d]imidazol-2-yl)phenyl (TPBi), or a mixture thereof. The electron transport region ETR may include a halogenated metal compound such as LiF, NaCl, CsF, RbCl, or RbI, a lanthanide metal such as Yb, a metal oxide such as Li₂O or BaO, Lithium quinolate (Liq), or the like.

The second electrode EL2 may be provided on the electron transport region ETR. The second electrode EL2 may be a common electrode or a negative electrode. The second electrode EL2 may be a transmissive electrode, a semi-transmissive electrode, or a reflective electrode. In an embodiment that the second electrode EL2 is a transmissive electrode, the second electrode EL2 may include a transparent metal oxide, for example, an indium tin oxide (ITO), an indium zinc oxide (IZO), a zinc oxide (ZnO), an indium tin zinc oxide (ITZO), or the like. In an embodiment that the second electrode EL2 is a semi-transmissive electrode or a reflective electrode, the second electrode EL2 may include at least one of Ag, Mg, Cu, Al, Pt, Pd, Au, Ni, Nd, Ir, Cr, Li, Ca, LiF/Ca, LiF/Al, Mo, Ti, Yb, a compound thereof, and a mixture thereof. In another embodiment, the second electrode EL2 may have a multilayer structure including a reflective film or semi-transmissive film, each of which is made of the foregoing material, and a transparent conductive film made of an indium tin oxide (ITO), an indium zinc oxide (IZO), a zinc oxide (ZnO), an indium tin zinc oxide (ITZO), etc.

Although not illustrated, the second electrode EL2 may be connected to an auxiliary electrode. In case that the second electrode EL2 is connected to an auxiliary electrode, the resistance of the second electrode EL2 may be reduced.

Referring FIGS. 3 and 4A, in the display device DD according to an embodiment, surface areas of the emission areas PXA-B, PXA-G and PXA-R may be different from each other. The “surface area” used herein may be a surface area in a plan view. For example, the emission areas PXA-B, PXA-G and PXA-R may have different surface areas according to emissive colors. For example, in the display device DD according to an embodiment, the blue emission area PXA-B which emits blue light may have a smallest surface area, and the green emission area PXA-G which generates green light may have a largest surface area. However, the disclosure is not limited thereto. In another embodiment, the emission areas PXA-B, PXA-G and PXA-R may emit light of colors other than blue light, green light, and red light, the emission areas PXA-B, PXA-G and PXA-R may have a same surface area, or the emission areas PXA-B, PXA-G and PXA-R may be provided in a different surface area ratio from those illustrated in FIG. 3. The emission areas PXA-B, PXA-G and PXA-R may have various polygonal shapes or circular shapes different from those illustrated in FIG. 3, and an arrangement structure of the emission areas is not limited. For example, in another embodiment, the emission areas PXA-B, PXA-G and PXA-R may have a PENTILE™ arrangement or have a diamond (Diamond Pixel™) arrangement.

The encapsulation layer TFE may be disposed on the light emitting element ED. The encapsulation layer TFE may cover the light emitting element ED. The encapsulation layer TFE may have a single-layer structure or a structure in which multiple layers are stacked each other. The encapsulation layer TFE may be a thin-film encapsulation layer. The encapsulation layer TFE may protect the light emitting element ED. The encapsulation layer TFE may cover a top surface of the second electrode EL2 disposed in the emission opening portion PDL-OP, and fill the emission opening portion PDL-OP.

The optical structure layers PP and PP-1 may each be disposed on the display element layer DP-EL. The optical structure layers PP and PP-1 may each have a function of converting at least a portion of a wavelength of light provided from the display panel DP, or preventing color mixture between adjacent emission areas. The optical structure layers PP and PP-1 may block external light provided to the display panels DP from the outside of the display devices DD and DD-1. The optical structure layers PP and PP-1 may perform antireflection functions to minimize reflection due to the external light.

The optical structure layers PP and PP-1 may include a light control layer CCL, a color filter layer CFL, an overcoat layer OC, and an anti-reflective layer ARL.

The light control layer CCL may include a photoconversion material. The photoconversion material may be a quantum dot, a phosphor, or the like. The photoconversion material may convert a wavelength of received light and emit the light. For example, the light control layer CCL may be a layer, at least a portion of which includes a quantum dot or a phosphor.

The light control layer CCL may be disposed on the display panel DP with a capping layer CPL between the light control layer CCL and the display panel DP. The light control layer CCL may include multiple partition wall portions BK which are spaced apart from each other, and light control portions CCP-B, CCP-G and CCP-R, each of which is disposed between the partition wall portions BK. The partition wall portions BK may include a polymer resin and a liquid-repellent additive. The partition wall portions BK may each include a light absorbing material or include a pigment or a dye. For example, the partition wall portion BK may include a black pigment or a black dye to be a black partition wall portion. When forming the black partition wall portion, a carbon black or the like may be used as a black pigment or a black dye, but the disclosure is not limited thereto.

The light control layer CCL may include a first light control portion CCP-B which converts source light provided from the light emitting element ED to first light, a second light control portion CCP-G which converts the source light to second light, and a third light control portion CCP-R which converts the source light to third light. The second light may be light in a longer-wavelength region than the first light, and the third light may be light in a longer-wavelength region than each of the first light and the second light. For example, the first light may be light having an emission wavelength in a range of about 410 nm to about 480 nm, the second light may be light having an emission wavelength in a range of about 500 nm to about 600 nm, and the third light may be light having an emission wavelength in a range of about 620 nm to about 700 nm. The first light may be blue light, the second light may be green light, and the third light may be red light.

The first light control portion CCP-B, the second light control portion CCP-G, and the third light control portion CCP-R may each include a luminous body. The luminous body may be a particle which converts a wavelength of incident light and emits light having a different wavelength. In an embodiment, the luminous body included in each of the first light control portion CCP-B, the second light control portion CCP-G, and the third light control portion CCP-R may be a quantum dot or a phosphor. The first light control portion CCP-B may include a first quantum dot QD1 which converts the source light to the first light, the second light control portion CCP-G may include a second quantum dot QD2 which converts the source light to the second light, and the third light control portion CCP-R may include a third quantum dot QD3 which converts the source light to the third light.

The quantum dot may include at least one of a Group II-VI compound, a Group I-II-VI compound, a Group II-IV-VI compound, a Group I-II-IV-VI compound, a Group III-VI compound, a Group I-III-VI compound, a Group III-V compound, a Group III-II-V compound, a Group II-IV-V compound, a Group IV-VI compound, a Group IV element, a Group IV compound, and a combination thereof.

The Group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound such as HgZnTeS, CdZnSeS, CdZnSeTe, CdZnSTe, CdHgSeS, CdHgSeTe, CdHgSTe, HgZnSeS, HgZnSeTe, and a mixture thereof. The Group II-VI compound may further include a Group I metal and/or a Group IV element. The Group I-II-VI compound may include CuSnS and CuZnS, the Group II-IV-VI compound may include ZnSnS and the like. The Group I-II-IV-VI compound may include a quaternary compound such as Cu₂ZnSnS₂, Cu₂ZnSnS₄, Cu₂ZnSnSe₄, Ag₂ZnSnS₂, and a mixture thereof.

The Group III-VI compound may include a binary compound such as In₂S₃ or In₂Se₃, a ternary compound such as InGaS₃ or InGaSe₃, or a combination thereof.

The Group I-III-VI compound may include: a ternary compound such as AgInS, AgInS₂, CuInS, CuInS₂, AgGaS₂, CuGaS₂, CuGaO₂, AgGaO₂, AgAlO₂, and a mixture thereof; and a quaternary compound such as AgInGaS₂ or CuInGaS₂.

The Group III-V compound may include: a binary compound such as GaN, GaP, GaAs, GaSb, AlN, AlP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; and a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group III-V compound may further include a Group II metal. For example, InZnP or the like may be selected as a Group III-II-V compound.

The Group II-IV-V compound may include a ternary compound such as ZnSnP, ZnSnP₂, ZnSnAs₂, ZnGeP₂, ZnGeAs₂, CdSnP₂, and CdGeP₂, and a mixture thereof.

The Group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; and a quaternary compound such as SnPbSSe, SnPbSeTe, SnPbSTe, and a mixture thereof. The Group IV element may include Si, Ge, and a mixture thereof. The Group IV compound may include SiC, SiGe, and a mixture thereof.

In the specification, a binary compound, a ternary compound, or a quaternary compound may be present at a uniform concentration in a particle, or may have partially different concentration distributions in a same particle. The compound may have a core/shell structure in which a quantum dot surrounds another quantum dot. The core/shell structure compound may have a concentration gradient in which the concentration of elements present in the shell gradually decreases toward the core.

In some embodiments, the quantum dot may have the aforementioned core-shell structure including a core including a nanocrystal and a shell surrounding the core. The shell of the quantum dot may serve as a protective layer for preventing a chemical change of the core to maintain semiconductor characteristics, and/or a charging layer for imparting electrophoretic characteristics to the quantum dot. The shell may be a single-layer shell or a multilayer shell. Examples of the shell may include a metal oxide, a nonmetal oxide, a semiconductor compound, or a combination thereof.

The shell the core may include different materials. For example, the core may include a first semiconductor nanocrystal, and the shell may include a second semiconductor nanocrystal different from the first semiconductor nanocrystal. In another embodiment, the shell may include a metal oxide or a nonmetal oxide. The shell may include a metal oxide or a nonmetal oxide, a semiconductor nanocrystal, or a combination thereof.

The shell may be made of a single material, but with a concentration gradient. For example, the shell may have a concentration gradient in which, in a direction that is closer to the core, a concentration of the second semiconductor nanocrystal present in the shell is gradually decreased, and a concentration of the first semiconductor nanocrystal included in the core is gradually increased. The shell may have a structure including multiple layers including different materials.

For example, a metal oxide or a nonmetal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but the disclosure is not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but the disclosure is not limited thereto.

The quantum dot may have a full width of half maximum (FWHM) of an emission wavelength spectrum less than or equal to about 45 nm. For example, the quantum dot may have a full width of half maximum (FWHM) of an emission wavelength spectrum less than or equal to about 40 nm. For example, the quantum dot may have a full width of half maximum (FWHM) of an emission wavelength spectrum less than or equal to about 30 nm. In this range, color purity or color reproducibility may be improved. Moreover, light emitted through such quantum dots may be emitted in all directions, thereby improving a wide viewing angle.

The form of the quantum dot may be a form generally used in the relevant field, and is not particularly limited. For example, spherical, pyramidal, multi-armed, or cubic nanoparticles, or particles in the form of nanotubes, nanowires, nanofibers, or nanoplate, or the like, may be used.

The quantum dots may adjust colors of emitted light according to the particle sizes, and accordingly, the quantum dots may have various emissive colors such as blue color, red color, and green color. As a particle size of the quantum dot is decreased, the quantum dot may emit light in a shorter-wavelength range. For example, in quantum dots having a same core, a particle size of the quantum dot which emits green light may be less than a particle size of the quantum dot which emits red light. In the quantum dots having a same core, a particle size of the quantum dot which emits blue light may be less than the particle size of the quantum dot which emits the green light. However, the disclosure is not limited thereto, and, even in the quantum dots having a same core, the particle sizes may be adjusted according to a material constituting the shell, a shell thickness, and the like.

In case that quantum dots have various emissive colors such as blue color, red color, and green color, the quantum dots may include different core materials.

The quantum dots may adjust colors of emitted light according to the material or the core.

Each of the control portions CCP-B, CCP-G and CCP-R included in the light control layer CCL may further include a scatterer SP. The first light control portion CCP-B may include the first quantum dot QD1 and the scatterer SP, the second light control portion CCP-G may include the second quantum dot QD2 and the scatterer SP, and the third light control portion CCP-R may include the third quantum dot QD3 and the scatterer SP.

The scatterer SP may be an inorganic particle. For example, the scatterer SP may include at least one of TiO₂, ZnO, Al₂O₃, SiO₂, and hollow silica. The scatterer SP may include at least one of TiO₂, ZnO, Al₂O₃, SiO₂, and hollow silica, or may be a mixture of two or more materials selected from TiO₂, ZnO, Al₂O₃, SiO₂, and hollow silica.

The first light control portion CCP-B, the second light control portion CCP-G, and the third light control portion CCP-R may include base resins BR1, BR2 and BR3 which disperse the quantum dots QD1, QD2 and QD3 and the scatterers SP, respectively. In an embodiment, the first light control portion CCP-B may include the first quantum dot QD1 and the scatterer SP dispersed in a first base resin BR1, the second light control portion CCP-G may include the second quantum dot QD2 and the scatterer SP dispersed in a second base resin BR2, and the third light control portion CCP-R may include the third quantum dot QD3 and the scatterer SP dispersed in a third base resin BR3. The base resins BR1, BR2 and BR3 may be mediums in which the quantum dots QD1, QD2 and QD3 and the scatterers SP are dispersed, and may include various resin compositions which may be generally referred to as binders. For example, the base resins BR1, BR2 and BR3 may each be an acrylic resin, a urethane-based resin, a silicon-based resin, an epoxy-based resin, or the like. The base resins BR1, BR2 and BR3 may each be a transparent resin. In an embodiment, the first base resin BR1, the second base resin BR2, and the third base resin BR3 may be the same or different from each other.

The light control layer CCL may further include the capping layer CPL. The capping layer CPL may be disposed on the light control portions CCP-B, CCP-G and CCP-R and the partition wall portion BK. The capping layer CPL may serve to prevent penetration of moisture and/or oxygen (hereinafter referred to as “moisture/oxygen”). The capping layer CPL may be disposed on the light control portions CCP-B, CCP-G and CCP-R and prevent the light control portions CCP-B, CCP-G and CCP-R from being exposed to moisture/oxygen. The capping layer CPL may include at least one inorganic layer.

An optical layer OPL may include the overcoat layer OC and the color filter layer CFL.

The color filter layer CFL may include color filters CF. The color filter layer CFL may include a first color filter CF-B which transmits the first light, a second color filter CF-G which transmits the second light, and a third color filter CF-R which transmits the third light. The color filter layer CFL may include the first color filter CF-B which transmits the blue light, the second color filter CF-G which transmits the green light, and the third color filter CF-R which transmits the red light. In an embodiment, the first color filter CF-B may be a blue filter, the second color filter CF-G may be a green filter, and the third color filter CF-R may be a red filter.

Each of the color filters CF may include a polymer photosensitive resin and a colorant. The first color filter CF-B may include a blue colorant, the second color filter CF-G may include a green colorant, and the third color filter CF-R may include a red colorant. The first color filter CF-B may include a blue pigment or a blue dye, the second color filter CF-G may include a green pigment or a green dye, and the third color filter CF-R may include a red pigment or a red dye.

The first to third color filters CF-B, CF-G and CF-R may be disposed to correspond to the first emission area PXA-B, the second emission area PXA-G, and the third emission area PXA-R, respectively. The first to third color filters CF-B, CF-G and CF-R may be disposed to correspond to the first to third light control portions CCP-B, CCP-G and CCP-R, respectively.

The color filters CF-B, CF-G and CF-R which transmit different light may overlap each other in a plan view so as to correspond to a peripheral area NPXA disposed between the emission areas PXA-B, PXA-G and PXA-R. The color filters CF-B, CF-G and CF-R may overlap each other in the third direction DR3 that is a thickness direction, thereby defining a boundary between adjacent emission areas among the emission areas PXA-B, PXA-G and PXA-R. Accordingly, an effect of blocking external light may be increased to have a function as, for example, a black matrix. A superposed structure of the color filters CF-B, CF-G and CF-R may have a function to prevent color mixture.

Unlike the illustrated embodiment, in another embodiment, the color filter layer CFL may include a light blocking part which defines a boundary between adjacent color filters among the color filters CF-B, CF-G and CF-R. The light blocking part may be provided as a blue filter or include an organic light blocking material or an inorganic light blocking material each including a black pigment or a black dye.

The color filter layer CFL may further include a buffer layer BFL. For example, the buffer layer BFL may be a protective layer which protects the color filters CF-B, CF-G and CF-R. The buffer layer BFL may be an inorganic layer including at least one inorganic material such as a silicon nitride, a silicon oxide, or a silicon oxynitride. The buffer layer BFL may include a single layer or multiple layers.

In an embodiment illustrated in FIG. 4A, the first color filter CF-B of the color filter layer CFL may overlap the second color filter CF-G and the third color filter CF-R in a plan view, but the disclosure is not limited thereto. For example, the first to third color filters CF-B, CF-G and CF-R may be divided by the light blocking part and not overlap each other. In an embodiment, the first to third color filters CF-B, CF-G and CF-R may be disposed to correspond to the blue emission area PXA-B, the green emission area PXA-G, and the red emission area PXA-R, respectively.

Although not illustrated, in another embodiment, the optical layer OPL of the display device DD may further include a polarizing layer (not illustrated). The polarizing layer may block external light provided to the display panel DP from the outside. The polarizing layer may block a portion of the external light. In an embodiment that the display device DD includes a polarizing layer, the color filter layer CFL may be omitted.

The polarizing layer may reduce reflected light generated in the display panel DP due to the external light. For example, the polarizing layer may function to block reflected light in case that the light provided from the outside of the display panel DP is incident on the display panel DP and emitted again. The polarizing layer may be a circular polarizer having an antireflection function, or the polarizing layer may include a linear polarizer and a λ/4 retarder. The polarizing layer may be disposed and exposed on the overcoat layer OC, or the polarizing layer may be disposed below the overcoat layer OC.

The overcoat layer OC may be disposed on the color filter layer CFL. The overcoat layer OC may include an organic layer. The overcoat layer OC may include an organic material having high strength and high planarization characteristics. The overcoat layer OC may provide a flat top surface. The overcoat layer OC may perform a function of an upper base layer which provides a reference surface of the color filter layer CFL. The overcoat layer OC may be a member which provides a base surface on which the optical layer OPL and the light control layer CCL are disposed. The overcoat layer OC may be an inorganic layer, an organic layer, or a composite material layer. However, the disclosure is not limited thereto, and the overcoat layer OC may be a glass substrate, a metal substrate, a plastic substrate, or the like.

The anti-reflective layer ARL may be disposed on the overcoat layer OC. The anti-reflective layer ARL may be disposed on (e.g., directly disposed on) the overcoat layer OC. For example, the anti-reflective layer ARL may be in contact with a top surface of the overcoat layer OC. The anti-reflective layer ARL may be a layer which has a low reflectance and thus blocks the external light. The anti-reflective layer ARL may be a layer which has multiple layers having different refractive indexes and thus effectively blocks the external light through destructive interference. A reflectance of a top surface of the anti-reflective layer ARL may be less than or equal to about 2%. In a visible light range of about 430 nm to about 780 nm, the reflectance of the top surface of the anti-reflective layer ARL may be less than or equal to about 2%. In a wavelength of about 550 nm, the reflectance of the top surface of the anti-reflective layer ARL may be less than or equal to about 2%.

Referring to FIG. 4B, the display device DD-1 according to an embodiment may include a display panel DP and an optical structure layer PP-1 disposed on the display panel DP. In the display device DD-1 according to an embodiment, the optical structure layer PP-1 may include an optical layer OPL-1 disposed on the display panel DP, and an anti-reflective layer ARL disposed on the optical layer OPL-1. The optical layer OPL-1 may include a light control layer CCL-1, a color filter layer CFL-1, and an overcoat layer OC-1 which are stacked in sequence.

The light control layer CCL-1 may be disposed on the display panel DP with a capping layer CPL interposed between the light control layer CCL-1 and the display panel DP. The light control layer CCL-1 may include multiple partition wall portions BK-1 and light control portions CCP-B1, CCP-G1 and CCP-R1, each of which is disposed between the partition wall portions BK-1.

The color filter layer CFL-1 may include a color filter part CF-1 including multiple filters CF-B, CF-G and CF-R, a light blocking part BM, and a buffer layer BFL.

Compared to the display device DD illustrated in FIG. 4A, the display device DD-1 according to an embodiment illustrated in FIG. 4B corresponds to an embodiment in which the light control layer CCL-1 and the color filter layer CFL-1 are disposed on a top surface of an encapsulation layer TFE as a base surface. For example, the light control portions CCP-B1, CCP-G1 and CCP-R1 of the light control layer CCL-1 may be formed on the display panel DP through a continuous process, and the filters CF-B, CF-G and CF-R of the color filter layer CFL-1 may be formed in sequence on the light control layer CCL-1 through a continuous process. The light control layer CCL-1 may be provided on, as a base surface, a top surface of the capping layer CPL disposed on the display panel DP, and have a shape inverted from the shape of the light control layer CCL illustrated in FIG. 4A. For example, each of the partition wall portions BK-1 and the light control portions CCP-B1, CCP-G1 and CCP-R1 may have a shape inverted from the shape illustrated in FIG. 4A. The color filter layer CFL-1 may be provided on a top surface of the light control layer CCL-1 as a base surface, and have a shape different from the shape illustrated in FIG. 4A.

In the color filter layer CFL-1 according to an embodiment, the light blocking part BM may be a black matrix. The light blocking part BM may include an organic light blocking material or an inorganic light blocking material each including a black pigment or a black dye. The light blocking part BM may prevent light leakage, and define a boundary between adjacent color filters among the color filters CF-B, CF-G and CF-R.

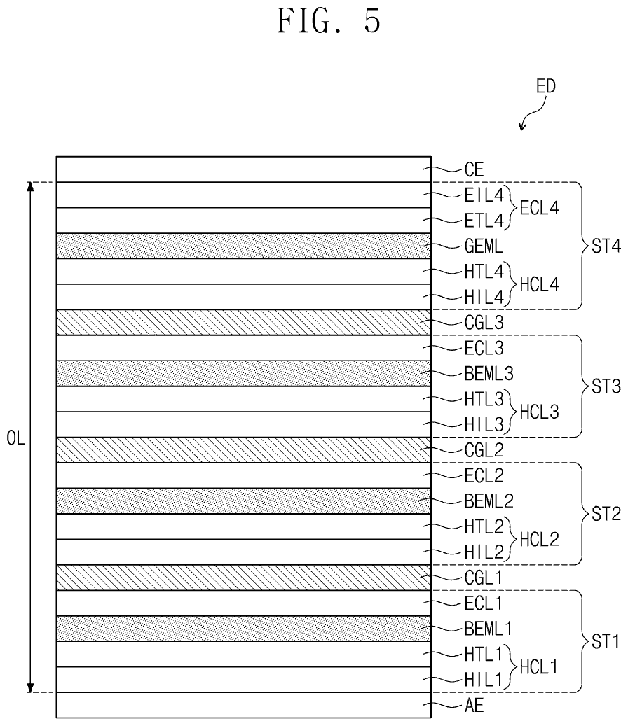

FIG. 5 is a schematic cross-sectional view of a light emitting element according to an embodiment of the disclosure.

Referring to FIG. 5, a light emitting element ED according to an embodiment may include a first electrode AE, a second electrode CE facing the first electrode AE, and first to fourth emission stacks ST1, ST2, ST3 and ST4 disposed between the first electrode AE and the second electrode CE. FIG. 5 illustrates that the light emitting element ED includes four emission stacks, but the disclosure is not limited thereto, and the number of the emission stacks included in the light emitting element ED may be less or more than four.

The light emitting element ED may include first to third charge generation layers CGL1, CGL2 and CGL3 disposed in respective spaces between the first to fourth emission stacks ST1, ST2, ST3 and ST4.

In case that a voltage is applied, each of the first to third charge generation layers CGL1, CGL2 and CGL3 may generate charges (electrons and holes) by forming a complex through an oxidation-reduction reaction. Thereafter, each of the first to third charge generation layers CGL1, CGL2 and CGL3 may provide the generated charges to adjacent stacks among the emission stacks ST1, ST2, ST3 and ST4. The first to third charge generation layers CGL1, CGL2 and CGL3 may increase the efficacy of current generated from the adjacent stacks ST1, ST2, ST3 and ST4, and may serve to adjust the balance of the charges between the adjacent stacks ST1, ST2, ST3 and ST4.

Each of the first to third charge generation layers CGL1, CGL2 and CGL3 may include an n-type layer and a p-type layer. The first to third charge generation layers CGL1, CGL2 and CGL3 may have a structure in which an n-type layer and a p-type layer are bonded to each other. However, the disclosure is not limited thereto, and the first to third charge generation layers CGL1, CGL2 and CGL3 may include only one of an n-type layer and a p-type layer. An n-type layer may be a charge generation layer that provides electrons to an adjacent stack. An n-type layer may be a layer in which a base material is doped with an n-dopant. A p-type layer may be a charge generation layer that provides holes to an adjacent stack.

In an embodiment, each of the first to third generation layers CGL1, CGL2 and CGL3 may have a thickness in a range of about 1 angstrom (Å) to about 150 angstroms (Å). The n-dopant doped in the first to third charge generation layers CGL1, CGL2 and CGL3 may have a concentration in a range of about 0.1% to about 3%. For example, the n-dopant doped in the first to third charge generation layers CGL1, CGL2 and CGL3 may have a concentration less than or equal to about 1%. In case that the concentration is less than about 0.1%, effects of the first to third charge generation layers CGL1, CGL2 and CGL3 that adjust the balance of the charges may hardly occur. In case that the concentration is more than about 3%, luminance efficiency of the light emitting element ED may be decreased.

Each of the first to third charge generation layers CGL1, CGL2 and CGL3 may include a charge generation compound including an aryl amine-based organic compound, a metal, an oxide, a carbide, a metal fluoride, or a mixture thereof. For example, an aryl amine-based organic compound may include α-NPD, 2-TNATA, TDATA, MTDATA, sprio-TAD, or sprio-NPB. A metal may include cesium (Cs), molybdenum (Mo), vanadium (V), titanium (Ti), tungsten (W), barium (Ba), or lithium (Li). An oxide, a carbide, and a metal fluoride may include Re₂O₇, MoO₃, V₂O₅, WO₃, TiO₂, Cs₂CO₃, BaF, LiF, or CsF. However, the materials of the first to third charge generation layers CGL1, CGL2 and CGL3 are not limited to the foregoing examples.

Each of the first to fourth emission stacks ST1, ST2, ST3 and ST4 may include an emission layer. The first emission stack ST1 may include a first emission layer BEML1, the second emission stack ST2 may include a second emission layer BEML2, the third emission stack ST3 may include a third emission layer BEML3, and the fourth emission stack ST4 may include a fourth emission layer GEML. Some of the emission layers included in the first to fourth emission stacks ST1, ST2, ST3 and ST4 may emit light of substantially the same color, and others of the emission layers included in the first to fourth emission stacks ST1, ST2, ST3 and ST4 may emit light of different colors.

In an embodiment, the first to third emission layers BEML1, BEML2 and BEML3 of the first to third emission stacks ST1, ST2 and ST3 may emit light of substantially the same first color. For example, the light of the first color may be blue light. The light emitted by the first to third emission layers BEML1, BEML2 and BEML3 may have a wavelength in a range of about 420 nm to about 480 nm.

The fourth emission layer GEML of the fourth emission stack ST4 may emit light of a second color different from the light of the first color. For example, the light of the second color may be green light. The light emitted by the fourth emission layer GEML may have a wavelength in a range of about 520 nm to about 600 nm.

An optical length OL may be a distance from the first electrode AE to the second electrode CE. In a case in which light is emitted between the first electrode AE corresponding to full-mirror and the second electrode CE corresponding to half-mirror, the optical length OL may serve as a resonance cavity. A resonance distance may be determined according to the optical length OL, and a light output ratio between the light of the first color and the light of the second color may be determined according to the resonance distance. For example, in case that the optical length OL increases, the resonance distance may increase, and accordingly, among the light of the first color and the light of the second color which are emitted at the same time, the light output ratio of light having a longer wavelength may increase. On the other hand, in case that the optical length OL decreases, the resonance distance may decrease, and accordingly, among the light of the first color and the light of the second color, the light output ratio of light having a shorter wavelength may increase. As the optical length OL decreases, a percentage of the light emitted from the first to third emission layers BEML1, BEML2 and BEML3 may be greater than a percentage of the light emitted from the fourth emission layer GEML. In an embodiment of the disclosure, a distance between the first electrode EL1 (see FIG. 4) and the second electrode EL2 (see FIG. 4) may be less than the resonance distance of the green light.

The light emitting element ED may emit light in a direction from the first electrode AE to the second electrode CE. In the light emitting element ED according to an embodiment, the emission stacks ST1, ST2, ST3 and ST4 may include hole transport regions HCL1, HCL2, HCL3 and HCL4 and electron transport regions ECL1, ECL2, ECL3 and ECL4, respectively. The hole transport regions HCL1, HCL2, HCL3 and HCL4 may transport, to the emission layers, holes provided from the first electrode AE or the charge generation layers CGL1, CGL2 and CGL3. The electron transport regions ECL1, ECL2, ECL3 and ECL4 may transport, to the emission layers, electrons provided from the second electrode CE or the charge generation layers CGL1, CGL2 and CGL3.

The light emitting element ED according to an embodiment is illustrated as having a structure in which, on the basis of a direction in which the light is emitted, the hole transport regions HCL1, HCL2, HCL3 and HCL4 are disposed below the emission layers BEML1, BEML2, BEML3 and GEML included in the emission stacks ST1, ST2, ST3 and ST4, respectively, and the electron transport regions ECL1, ECL2, ECL3 and ECL4 are disposed above the emission layers BEML1, BEML2, BEML3 and GEML included in the emission stacks ST1, ST2, ST3 and ST4, respectively. For example, the light emitting element ED according to an embodiment may have a forward device structure. However, the disclosure is not limited thereto, and the light emitting element ED may have an inverted device structure in which, on the basis of the direction in which the light is emitted, the electron transport regions ETR1, ETR2, ETR3 and ETR4 are disposed below the emission layers BEML1, BEML2, BEML3 and GEML included in the emission stacks ST1, ST2, ST3 and ST4, respectively, and the hole transport regions HCL1, HCL2, HCL3 and HCL4 are disposed above the emission layers BEML1, BEML2, BEML3 and GEML included in the emission stacks ST1, ST2, ST3 and ST4, respectively.

The hole transport regions HCL1, HCL2, HCL3 and HCL4 may include hole injection layers HIL1, HIL2, HIL3 and HIL4, and hole transport layers HTL1, HTL2, HTL3 and HTL4 disposed on the hole injection layers HIL1, HIL2, HIL3 and HIL4, respectively. Each of the hole transport layers HTL1, HTL2, HTL3 and HTL4 may be in contact with a bottom surface of the emission layer. However, the disclosure is not limited thereto, and the hole transport regions HCL1, HCL2, HCL3 and HCL4 may further include hole side additional layers disposed on the hole transport layers HTL1, HTL2, HTL3 and HTL4, respectively. The hole side additional layer may include at least one of a hole buffer layer, an emission auxiliary layer, and an electron blocking layer. The hole buffer layer may be a layer that compensates for a resonance distance according to wavelengths of light emitted from the emission layer and increases light emission efficiency. The electron blocking layer may be a layer that serves to prevent electrons from being injected from an electron transport region into a hole transport region.

The electron transport regions ECL1, ECL2, ECL3 and ECLA may include an electron transport layer. The electron transport regions ECL1, ECL2, ECL3 and ECL4 may further include an electron injection layer disposed on the electron transport layer. For example, a fourth electron transport region ECL4 included in the fourth emission stack ST4 may further include a fourth electron transport layer ETL4 and a fourth electron injection layer EIL4 disposed on the fourth electron transport layer ETL4. The electron transport regions ECL1, ECL2, ECL3 and ECL4 may further include an electron side additional layer disposed between the electron transport layer and the emission layers. The electron side additional layer may include at least one of an electron buffer layer and a hole blocking layer.

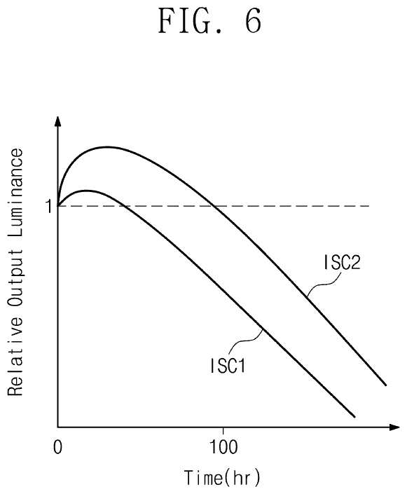

FIG. 6 is a graph showing a time-relative output luminance curve for a display panel. For concise explanation, FIG. 6 shows an image sticking compensation (ISC) graph for light emitting elements having different optical lengths.

An image sticking compensation (ISC) curve (or time-relative output luminance curve) may be an estimated lifespan graph obtained by calculating a luminance maintenance rate data by degradation conditions. Here, the ISC curve may be a curve of estimated attenuation of a display panel according to degradation, derived based on a luminance acceleration relation calculated using difference data of only degradation luminance at the same temperature, and temperature acceleration relations calculated using difference data of only degradation temperature at the same luminance.

Assuming that a maximum luminance value (or an initial luminance value) in the ISC curve is about 1, a period of time in which a relative value of an output luminance value with respect to the maximum luminance value is greater than about 1 may occur. Overshoot may be a phenomenon of occurrence of the period of time in which the relative value of the output luminance value with respect to the maximum luminance value in the ISC curve is greater than about 1. Hereinafter, a degree to which the overshoot occurs may be referred to as an overshoot character (or an overshoot value). In the disclosure, the overshoot value may be a ratio of the output luminance value to the initial luminance value which exceeds about 1, and a maximum overshoot value may be a maximum value of ratios of the output luminance value to the initial luminance value which exceed about 1.

Referring to FIG. 6, an overshoot character of a second curve ISC2 may be greater than an overshoot character of a first curve ISC1. The second curve ISC2 may be greater than the first curve ISC1 in degree of occurrence of the period of time in which the relative value of the output luminance value with respect to the initial luminance value is greater than about 1. The maximum overshoot value in the second curve ISC2 may be greater than the maximum overshoot value in the first curve ISC1. The first curve ISC1 may be an ISC curve derived from data calculated in case that the optical length is about 419.78 nm, and the second curve ISC2 may be an ISC curve derived from data calculated in case that the optical length is about 411.594 nm. For example, the smaller the optical length is, the stronger the overshoot character of an emission layer may be. In case that the overshoot occurs, reliability of the display panel may be decreased due to overcompensation for image sticking of the display panel.

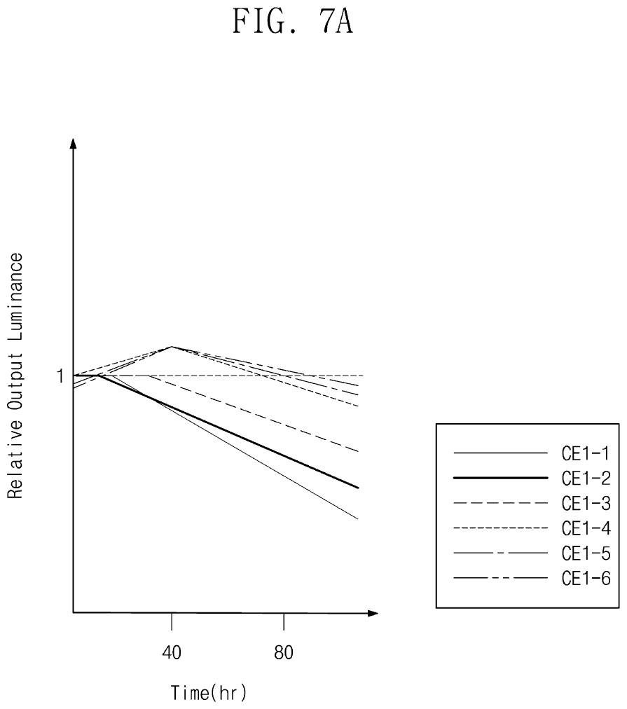

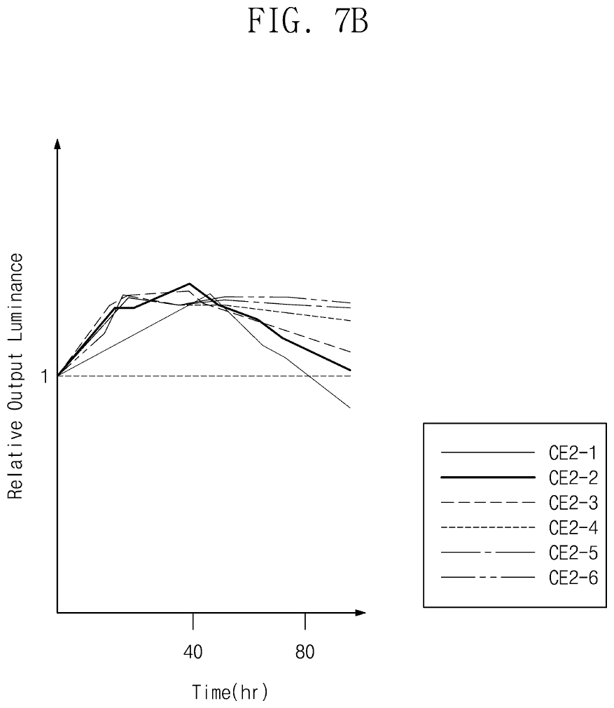

FIG. 7A is a time-relative output luminance curve for a display panel according to Comparative Example. FIG. 7B is a time-relative output luminance curve for a display panel according to Comparative Example.

Referring to FIG. 7A, the time-relative output luminance curve for the display panel according to Comparative Example may include (1-1)-th, (1-2)-th, (1-3)-th, (1-4)-th, (1-5)-th, and (1-6)-th curves CE1-1, CE1-2, CE1-3, CE1-4, CE1-5 and CE1-6. Here, the (1-1)-th, (1-2)-th, (1-3)-th, (1-4)-th, (1-5)-th, and (1-6)-th curves CE1-1, CE1-2, CE1-3, CE1-4, CE1-5 and CE1-6 may be curves illustrating results measured in case that observation gradations are about 16, about 32, about 64, about 128, about 192, and about 255, respectively.

Referring to FIG. 7B, the time-relative output luminance curve for the display panel according to Comparative Example may include (2-1)-th, (2-2)-th, (2-3)-th, (2-4)-th, (2-5)-th, and (2-6)-th curves CE2-1, CE2-2, CE2-3, CE2-4, CE2-5 and CE2-6. Here, the (2-1)-th, (2-2)-th, (2-3)-th, (2-4)-th, (2-5)-th, and (2-6)-th curves CE2-1, CE2-2, CE2-3, CE2-4, CE2-5 and CE2-6 may be curves illustrating results measured in case that the observation gradations are about 16, about 32, about 64, about 128, about 192, and about 255, respectively.

In general, an observation gradation for obtaining a stable data value may be about 64 or more. In general, a gradation for observing the image sticking of the display panel may be about 64 or about 128.

FIG. 7A may be a time-relative output luminance curve per observation gradation, based on luminance maintenance rate data of light (or second light) passing through a green color filter. FIG. 7B may be a time-relative output luminance curve per gradation, based on luminance maintenance rate data of light (or first light) passing through a blue color filter.

Assuming that an initial luminance value is about 1, a relative output luminance may be a relative value of an output luminance value with respect to the initial luminance value. For example, the relative output luminance may be a value that is the output luminance value divided by the initial luminance value. An overshoot character of the display panel may be greater in case that the relative output luminance has a value exceeding about 1.

Referring FIG. 7A, the (1-4)-th to (1-6)-th curves CE1-4, CE1-5 and CE1-6 may each include a period of time in which the relative output luminance has the value exceeding about 1. On the other hand, the (1-1)-th to (1-3)-th curves CE1-1, CE1-2 and CE1-3 may not include the period of time in which the relative output luminance has the value exceeding about 1. In the light passing through the green color filter, the period of time in which the relative output luminance has the value exceeding about 1 may occur only in case that the observation gradation is about 128 or more. For example, with respect to the light passing through the green color filter, overshoot may occur only at a specific observation gradation or greater.

Referring FIG. 7B, the (2-1)-th to (2-6)-th curves CE2-1, CE2-2, CE2-3, CE2-4, CE2-5 and CE2-6 may each include the period of time in which the relative output luminance has the value exceeding about 1. In the light passing through the blue color filter, the period of time in which the relative output luminance has the value exceeding about 1 may occur regardless of the observation gradation. For example, with respect to the light passing through the blue color filter, the overshoot may occur regardless of the observation gradation.

Referring to FIGS. 7A and 7B, the first light may be stronger than the second light in overshoot character. For example, the first light may be stronger than the second light in degree to which the relative output luminance has the value exceeding about 1. As an optical length decreases, a light output ratio of light having a shorter wavelength may be greater than a light output ratio of light having a longer wavelength. As the optical length decreases, a light output ratio of blue light may be greater than a light output ratio of green light. A wavelength of the first light may be shorter than a wavelength of the second light. For example, as the optical length decreases, a light output ratio of the first light may be greater than a light output ratio of the second light. As described above, since the overshoot character of the first light is stronger than the overshoot character of the second light, as the light output ratio of the first light increases, a total overshoot value of the display panel may increase.

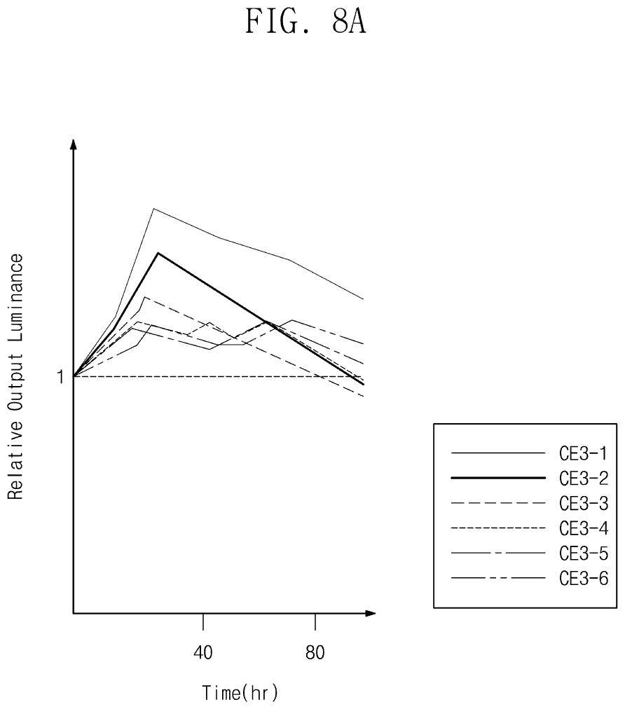

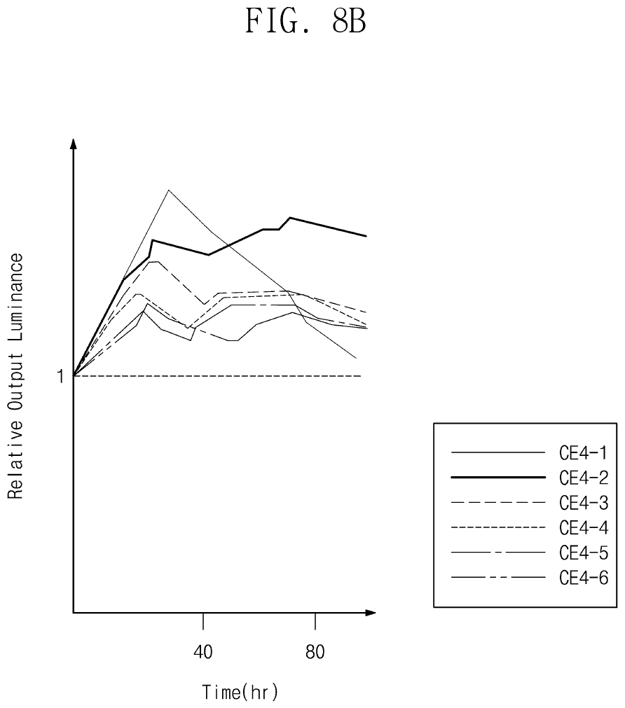

FIG. 8A is a time-relative output luminance curve for a display panel according to an embodiment of the disclosure. FIG. 8B is a time-relative output luminance curve for a display panel according to an embodiment of the disclosure. FIGS. 8A and 8B are each the time-relative output luminance curve for the display panel including a pixel defining film PDL including at least one of a black pigment or a black dye.

Referring to FIG. 8A, a time-relative output luminance curve for a display panel according to Comparative Example may include (3-1)-th, (3-2)-th, (3-3)-th, (3-4)-th, (3-5)-th, and (3-6)-th curves CE3-1, CE3-2, CE3-3, CE3-4, CE3-5 and CE3-6. Here, the (3-1)-th, (3-2)-th, (3-3)-th, (3-4)-th, (3-5)-th, and (3-6)-th curves CE3-1, CE3-2, CE3-3, CE3-4, CE3-5 and CE3-6 may be curves showing results measured in case that observation gradations are about 16, about 32, about 64, about 128, about 192, and about 255, respectively.

Referring to FIG. 8B, a time-relative output luminance curve for a display panel according to Comparative Example may include (4-1)-th, (4-2)-th, (4-3)-th, (4-4)-th, (4-5)-th, and (4-6)-th curves CE4-1, CE4-2, CE4-3, CE4-4, CE4-5 and CE4-6. Here, the (4-1)-th, (4-2)-th, (4-3)-th, (4-4)-th, (4-5)-th, and (4-6)-th curves CE4-1, CE4-2, CE4-3, CE4-4, CE4-5 and CE4-6 may be curves showing results measured in case that the observation gradations are about 16, about 32, about 64, about 128, about 192, and about 255, respectively.

FIG. 8A may be a time-relative output luminance curve for a display panel with improved lifetime characteristics, the display panel including emission layers (hereinafter referred to as green emission layers) which generate green light. FIG. 8A shows the time-relative output luminance curve for the display panel including a black pixel defining film, but the disclosure is not limited thereto.

As described above, in case that the pixel defining film includes a black pigment, an amount of outgassing may be decreased, thereby providing a light emitting element with improved lifetime characteristics. As the green emission layer includes a phosphorescent material unlike a blue emission layer including a fluorescent material, the green emission layer may have lower durability than the blue emission layer and may have shorter lifespan than the blue emission layer. In case that the pixel defining film includes a black pigment, a degree to which lifetime characteristics of the green emission layer are improved may be greater than a degree to which lifetime characteristics of the blue emission layer are improved. Accordingly, the lifetime of the green emission layer may be similar to the lifetime of the blue emission layer. As the lifetime characteristics of the green emission layer are improved, an overshoot character of light (or the second light) passing through a green color filter may be increased together. For example, a degree of occurrence of a period of time in which an output luminance value exceeding an initial luminance value is generated may be increased before degradation of the light emitting element. Accordingly, the overshoot character of the light (or the second light) passing through the green color filter may be similar to an overshoot character of light (or the first light) passing through a blue color filter.

Referring to FIG. 8A, in FIG. 8A unlike FIG. 7A in which the overshoot is observed in only the curves measured at 128, 192, and 255 gradations, the overshoot may be observed in all the curves measured at 16, 32, 64, 128, 192, and 255 gradations. For example, not only the (3-4)-th to (3-6)-th curves CE3-4, CE3-5 and CE3-6 measured at the 128, 192, and 255 gradations, but also the (3-1)-th to (3-3)-th curves CE3-1, CE3-2 and CE3-3 measured at the 16, 32, and 64 gradations may each include a period of time in which a relative output luminance has a value exceeding about 1. As the lifetime characteristics of the green emission layer are improved, the period of time which the relative output luminance has the value exceeding about 1 may occur regardless of the observation gradation.

Referring to FIGS. 8A and 8B, as the lifetime characteristics of the green emission layer and the lifetime characteristics of the blue emission layer become similar as described above, the overshoot character of the first light and the overshoot character of the second light may become similar. For example, the first light and the second light may become similar in terms of a degree to which the relative output luminance has the value exceeding about 1. In both the first light and the second light, the period of time in which the relative output luminance has the value exceeding about 1 may occur regardless of the observation gradation. In both the first light and the second light, the overshoot may occur regardless of the observation gradation.

Equation 1 below represents a total overshoot value of the display panel.

Total overshoot value=α×OS1+b×OS2 [Equation 1]

In Equation 1, a may be a light output ratio of blue light, and b may be a light output ratio of green light. A value obtained by adding a and b may be about 1. OS1 may be an overshoot value of the light passing through the blue color filter. OS2 may be an overshoot value of the light passing through the green color filter.

Referring to Equation 1 above, in case that the overshoot value of the light passing through the green color filter and the overshoot value of the light passing through the blue color filter become similar, a and b may become similar, and thus a total of the overshoot values of the display panel may be determined regardless of an optical length. In other words, in case that the overshoot value of the light passing through the green color filter and the overshoot value of the light passing through the blue color filter are similar, the optical length may be decreased, and thus, even in case that a ratio at which the blue light is emitted is increased, the total of the overshoot values of the display panel may not be affected. According to an embodiment of the disclosure, the overshoot may be generated in the green light similar to the overshoot value of the blue light, thereby controlling an output overshoot value to be in a predictable range regardless of a change in optical length. Thus, the display panel which readily compensates for image sticking of the light generated from the light emitting element and is improved in display characteristics may be provided.

In case that the relative value of the output luminance value with respect to the initial luminance value in the display panel is less than or equal to about 1.02, overcompensation for the image sticking of the display panel may be prevented. In order that the relative value of the output luminance value with respect to the initial luminance value in the display panel is less than or equal to about 1.02, a difference value between the overshoot value of the light passing through the green color filter and the overshoot value of the light passing through the blue color filter may be less than or equal to about 0.01.

According to an embodiment of the disclosure, the respective overshoot values of the first light and the second light which have different wavelengths may be set to be in similar ranges, thereby readily compensating for the image sticking of the light output from the light emitting element. In an embodiment of the disclosure, the black pixel defining film may be used to design the overshoot values to be in similar ranges, but the disclosure is not limited thereto. As long as a difference between the overshoot values of the first light and the second light is less than or equal to about 0.01, the designing may be performed through various methods, for example, adjusting a light emitting material, and is not limited to any one embodiment.

According to the embodiment of the disclosure, the emission layers which emit the blue light and the emission layers which emit the green light may have the similar ranges of the degree of occurrence of the period of time in which the relative value of the output luminance value with respect to the initial luminance value is greater than about 1, thereby providing the electronic device capable of effectively compensating for the image sticking.

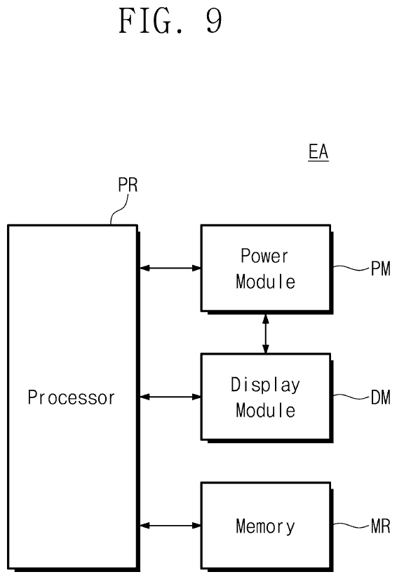

FIG. 9 is a block diagram illustrating an electronic device according to an embodiment.

Referring to FIG. 9, an electronic device EA according to an embodiment may include a display module DM, a processor PR, a memory MR, and a power module PM.

The processor PR may include at least one a central processing unit (CPU), an application processor (AP), a graphic processing unit (GPU), a communication processor (CP), an image signal processor (ISP), or a controller.

The memory MR may store data information necessary for the operation of the processor PR or the display module DM. When the processor PR runs the application stored in the memory MR, an image data signal and/or an input control signal may be transmitted to the display module DM, and the display module DM may process the transmitted signal and output the image information through the display screen. The display module DM may include a display panel to display an image.

The power module PM may include a power converting module. The power converting module may convert power, which is supplied from a power supply module, such as a power adaptor or a battery device, into power necessary for the operation of the electronic device EA.

At least one of components of the above-described electronic device EA may be included in the display module according to embodiments and a display device, which includes the display module, according to an embodiment. In addition, some of individual modules functionally included in one module may be included in the display device, and others of the individual modules may be provided separately from the display device. For example, the display device may include the display module DM, and the processor PR, the memory MR, and the power module PM may be provided in the form of another device in the electronic device EA instead of the display device.

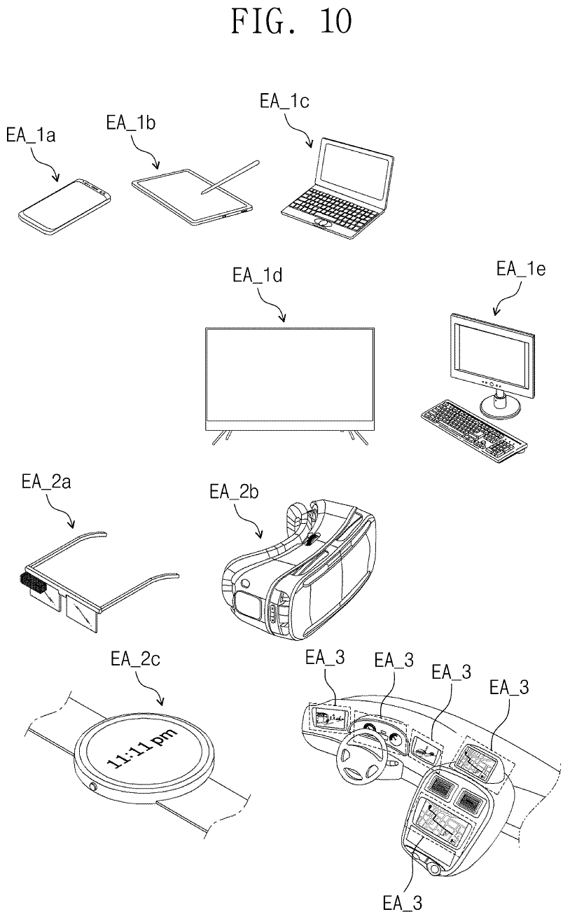

FIG. 10 is a view schematically illustrating various electronic devices according to embodiments.

Referring to FIG. 10, the various electronic devices including the display module according to an embodiment may include a wearable electronic device such as smart glasses EA_2a, a head mounted display EA_2b, and a smart watch EA_2c, and an electronic device EA-3 for the vehicle such as a center information display (CID), which is disposed in an instrument panel, a center fascia, and a dashboard of a vehicle, or a room mirror display, as well as an electronic device for image display such as a smartphone EA_1a, a tablet PC EA_1b, a laptop computer EA_1c, a television TV (EA_1d) and a desk monitor EA_1e.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An electronic device comprising:
a pixel defining film defining a plurality of emission areas and a non-emission area adjacent to the plurality of emission areas;
a plurality of light emitting elements which are disposed in the plurality of emission areas, respectively, and each of which emits source light; and
an optical layer disposed on the plurality of light emitting elements, wherein
each of the plurality of light emitting elements comprises:
a first electrode disposed in the plurality of emission areas;
a first emission layer disposed on the first electrode and generating first light of a blue color;
a second emission layer disposed on the first emission layer and generating second light of a green color;
a third emission layer disposed between the first emission layer and the second emission layer and generating third light of the blue color;
a fourth emission layer disposed between the first emission layer and the second emission layer and generating fourth light of the blue color;
a charge generation layer disposed between the first emission layer and the second emission layer; and
a second electrode disposed on the second emission layer,
the pixel defining film comprises a pigment having a black color, and
a distance between the first electrode and the second electrode is less than a resonance distance of green light.

2. The electronic device of claim 1, wherein a maximum value of differences between a maximum overshoot value of the second light and a maximum overshoot value of each of the first light, the third light, and the fourth light is about 0.01.

3. The electronic device of claim 2, wherein the maximum overshoot value is measured at 64-gradation or 128-gradation.

4. The electronic device of claim 1, wherein wavelengths of at least two of the first light, the third light, and the fourth light are different from each other.

5. The electronic device of claim 4, wherein the wavelengths are in a range of about 440 nm to about 610 nm.

6. The electronic device of claim 1, wherein the optical layer comprises a color filter layer comprising a color filter.

7. The electronic device of claim 6, wherein the optical layer further comprises a light control layer comprising a quantum dot.

8. The electronic device of claim 1, wherein each of the first emission layer, the third emission layer, and the fourth emission layer comprises a plurality of stacked layers.

9. An electronic device comprising:
a display module configured to display an image; and
a processor configured to provide image data to the display module,
wherein the display module comprises:
a pixel defining film defining a plurality of emission areas and a non-emission area adjacent to the plurality of emission areas;
a plurality of light emitting elements which are disposed in the plurality of emission areas, respectively, and each of which emits source light; and
an optical layer disposed on the plurality of light emitting elements, wherein
each of the plurality of light emitting elements comprises:
a first electrode disposed in the plurality of emission areas;
a second electrode disposed on the first electrode;
a first emission layer disposed between the first electrode and the second electrode and generating first light;
a second emission layer disposed between the first electrode and the second electrode and generating second light, the first light and the second light having different colors; and
a charge generation layer disposed between the first emission layer and the second emission layer,
each of the first light and the second light has an overshoot value having a luminance higher than an initial luminance for a period of time, and
a difference between a maximum overshoot value of the first light and a maximum overshoot value of the second light is about 0.01.

10. The electronic device of claim 9, wherein a wavelength of the first light is shorter than a wavelength of the second light.

11. The electronic device of claim 9, wherein
each of the plurality of light emitting elements further comprises a third emission layer and a fourth emission layer, and
the third emission layer and the fourth emission layer generate light of a same color as the first light.

12. The electronic device of claim 11, wherein
the second emission layer is disposed on the first emission layer, and
the third emission layer and the fourth emission layer are disposed between the first emission layer and the second emission layer.

13. The electronic device of claim 11, wherein each of the first emission layer, the third emission layer, and the fourth emission layer comprises a plurality of stacked layers.

14. The electronic device of claim 11, wherein wavelengths of lights from at least two of the first emission layer, the third emission layer, and the fourth emission layer are different from each other.

15. The electronic device of claim 14, wherein the wavelengths are in a range of about 440 nm to about 610 nm.

16. The electronic device of claim 9, wherein the pixel defining film comprises at least one of a black pigment and a black dye.

17. The electronic device of claim 9, wherein the optical layer comprises a color filter layer comprising a color filter.

18. The electronic device of claim 17, wherein the optical layer further comprises a light control layer comprising a quantum dot.

19. The electronic device of claim 9, wherein a distance between the first electrode and the second electrode is less than a resonance distance of the second light.

20. The electronic device of claim 9, wherein the maximum overshoot value is measured at 64-gradation or 128-gradation.
